(19) United States
(12) Patent Application Publication
(10) Pub. No.: US 2026/0184173 A1
(43) Pub. Date: Jul. 2, 2026

(54) FLEXIBLE DISPLAY DEVICE

(71) Applicant: LG Display Co., Ltd., Seoul (KR)

(72) Inventors: Wooseok CHO, Gumi-si (KR); SungSik SON, Daegu (KR)

(73) Assignee: LG Display Co., Ltd., Seoul (KR)

(21) Appl. No.: 19/200,409

(22) Filed: May 6, 2025

(30) Foreign Application Priority Data
Dec. 30, 2024 (KR) 10-2024-0200172

(51) Int. Cl. B60K 35/53; B60K 35/22; G06F 1/16; G06F 1/18; G06F 1/20

(52) U.S. Cl. CPC B60K 35/53; B60K 35/223; G06F 1/1601; G06F 1/183; G06F 1/20; B60K 2360/126

(57) ABSTRACT

A flexible display device may include a display panel, a mid-back plate, a first side back plate, and a second side back plate disposed on a back surface of the display panel and a driving module for rotating the first side back plate and the second side back plate with respect to the mid-back plate, wherein the driving module includes a first shaft rotatably disposed on a back surface of the mid-back plate, a second shaft pivotally disposed on a back surface of the first side back plate and pivoted by receiving a rotational force from the first shaft, a third shaft pivotally disposed on a back surface of the second side back plate and pivoted by receiving a rotational force from the first shaft, and a motor disposed on the back surface of the mid-back plate and for rotating the first shaft.

### CROSS-REFERENCE TO RELATED APPLICATIONS

This application claims the priority of Korean Patent Application No. 10-2024-0200172 filed on Dec. 30, 2024, in the Korean Intellectual Property Office, the disclosure of which is incorporated herein by reference.

### BACKGROUND

### Technical Field

The present disclosure relates to a flexible display device, and more particularly, to a bendable flexible display device.

### Discussion of the Related Art

Due to the advancement of display technology, various forms of display devices are being developed. In particular, as display panels with flexible characteristics are commercialized, interest in display devices that can change shape depending on the usage environment is increasing, moving away from flat displays.

Conventional flexible display devices have adopted a method of forcibly bending the display panel thereof, which has resulted in a problem of reduced durability of the display panel. In addition, there has been a problem of the complex structure of the mechanical device for driving (or facilitating) the bending of the display panel.

### SUMMARY

Accordingly, embodiments of the present disclosure are directed to a flexible display device that substantially obviates one or more of the problems due to limitations and disadvantages of the related art.

An aspect of the present disclosure is to provide a flexible display device that is bendable with a simple mechanical structure.

Another aspect of the present disclosure is to provide a flexible display device that can be stably bent while suppressing an excessive stress applied to a display panel thereof.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a flexible display device comprises a display panel, a plurality of back plates (in other words, at least two back plates, for example, three back plates consisting of a mid-back plate, a first side back plate, and a second side back plate, but not limited thereto) disposed on a back surface of the display panel and a driving module for rotating at least one of the plurality of back plates with respect to another one of the plurality of back plates so that the display panel can be bent (for example, the driving module is configured to rotate the first side back plate and the second side back plate with respect to the mid-back plate, but not limited thereto), wherein the driving module includes a rotatable shaft rotatably disposed on a back surface of the another one of the plurality of back plates, a pivotable shaft pivotally disposed on a back surface of the at least one of the plurality of back plates and pivoted by receiving a rotational force from the rotatable shaft, and a rotary power driving source disposed on the back surface of the another one of the plurality of back plates and for rotating the rotatable shaft (for example, the driving module includes a first shaft rotatably disposed on a back surface of the mid-back plate, a second shaft pivotally disposed on a back surface of the first side back plate and pivoted by receiving a rotational force from the first shaft, a third shaft pivotally disposed on a back surface of the second side back plate and pivoted by receiving a rotational force from the first shaft, and a motor disposed on the back surface of the mid-back plate and for rotating the first shaft, but not limited thereto).

In another aspect, a flexible display device comprises a cover window, a display panel disposed on a back surface of the cover window, a plurality of back plates (for example, a mid-back plate, a first side back plate, and a second side back plate, but not limited thereto) disposed on a back surface of the display panel, a coupling member disposed on a back surface of at least one of the plurality of back plates and coupled with a pivotable shaft, another coupling member disposed on a back surface of another one of the plurality of back plates and into which a rotatable shaft is inserted, and a rotary power driving source for rotating the rotatable shaft, wherein the pivotable shaft is pivoted by receiving a rotational force from the rotatable shaft, and the at least one of the plurality of back plates is rotated with respect to the another one of the plurality of back plates by the pivoting of the pivotable shaft, so that the display panel and the cover window can be bent together (for example, the coupling member and the another coupling member include a first coupling member disposed on a back surface of the mid-back plate and into which a first shaft is inserted, a second coupling member disposed on a back surface of the first side back plate and coupled with a second shaft; a third coupling member disposed on a back surface of the second side back plate and coupled with a third shaft, and the the rotary power driving source is configured to be a motor for rotating the first shaft, wherein the second shaft and the third shaft are pivoted by receiving a rotational force from the first shaft, and the first side back plate and the second side back plate are rotated counterclockwise and clockwise respectively with respect to the mid-back plate by the pivoting of the second shaft and the third shaft, so that the display panel and the cover window can be bent together, but not limited thereto).

Other detailed matters of the exemplary embodiments are included in the detailed description and the drawings.

The flexible display device according to an embodiment of the present disclosure can improve durability by minimizing stress applied to the display panel by applying the structure in which the first side back plate and the second side back plate can pivot with respect to the mid-back plate.

The flexible display device according to an embodiment of the present disclosure can reduce manufacturing costs by applying a simple driving mechanism in which the rotational force of the first shaft is transmitted to the second shaft and the third shaft through inclined surfaces of the first shaft, the second shaft and the third shaft.

The flexible display device according to an embodiment of the present disclosure can implement a lightweight flexible display device by bending the display device using a simple driving mechanism.

The flexible display device according to an embodiment of the present disclosure can effectively dissipate heat from a PCB through a heat dissipation hole, thereby improving the reliability of the display device.

The flexible display device according to an embodiment of the present disclosure can be accommodated (in other words, retracted) into a housing by a lifting/lowering module in a bent state, thereby improving user convenience.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is an exploded perspective view of a flexible display device according to one embodiment of the present disclosure.

FIG. 2 is a perspective view of the flexible display device according to one embodiment of the present disclosure.

FIG. 3 is a rear view of the flexible display device according to one embodiment of the present disclosure.

FIG. 4 is a plan view of the flexible display device according to one embodiment of the present disclosure.

FIG. 5 is a perspective view illustrating an appearance of the flexible display device according to one embodiment of the present disclosure after a bending operation.

FIG. 6 is a plan view illustrating the appearance of the flexible display device according to one embodiment of the present disclosure after the bending operation.

FIG. 7 is a perspective view of a driving module of the flexible display device according to one embodiment of the present disclosure.

FIG. 8 is a perspective view illustrating an appearance of the driving module of the flexible display device according to one embodiment of the present disclosure after the bending operation.

FIG. 9 is a plan view illustrating a driving process of first to third shafts of the flexible display device according to one embodiment of the present disclosure.

FIG. 10 is a perspective view illustrating an appearance of the flexible display device according to one embodiment of the present disclosure being accommodated in a housing.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, yet another element or layer may be interposed directly on the another element or layer, or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

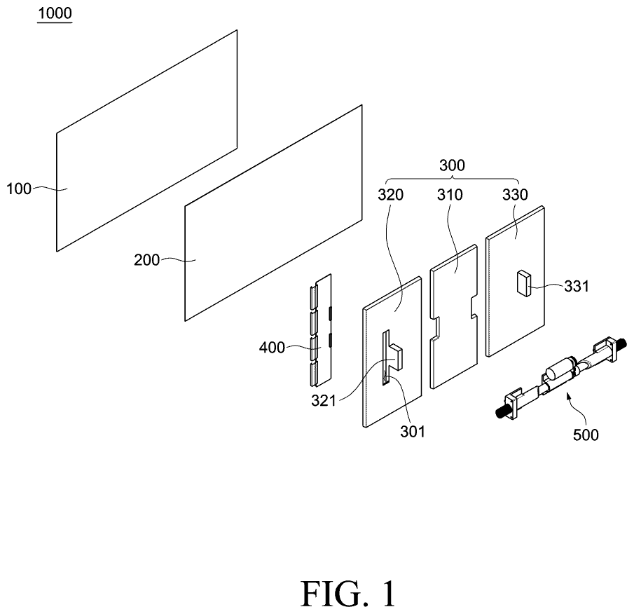

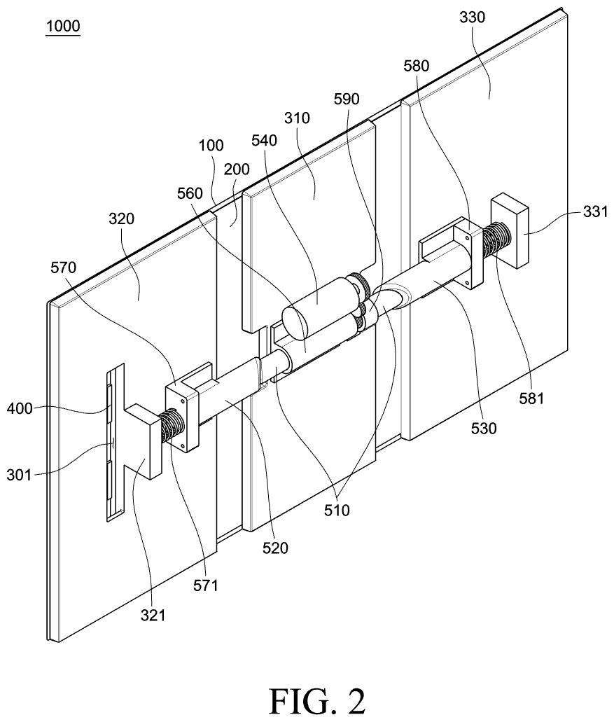

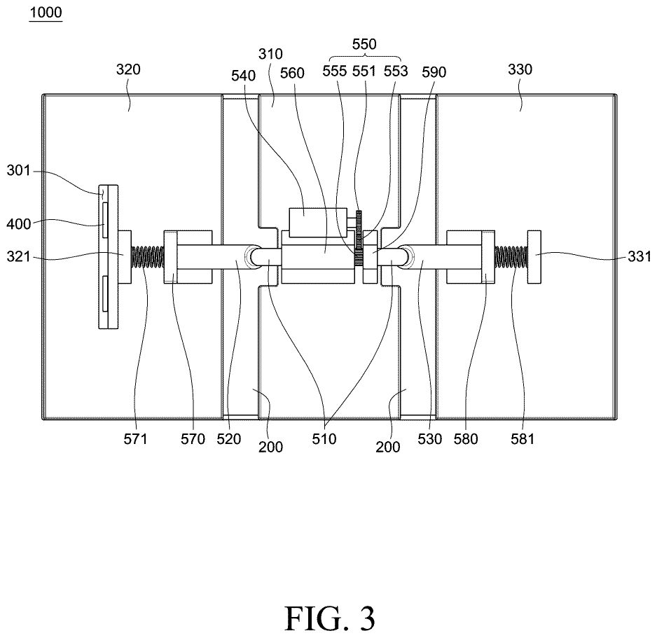

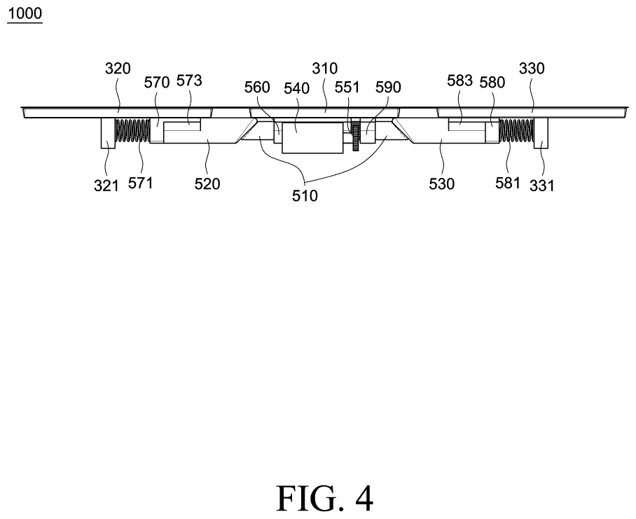

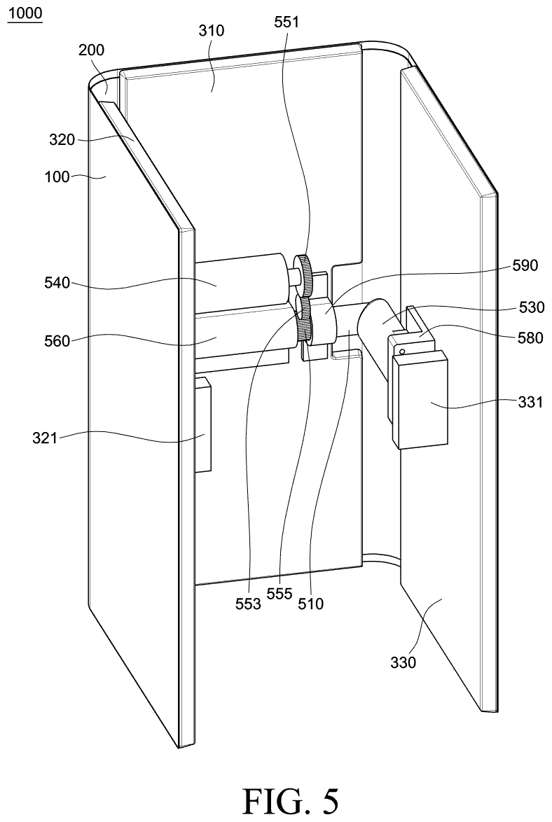

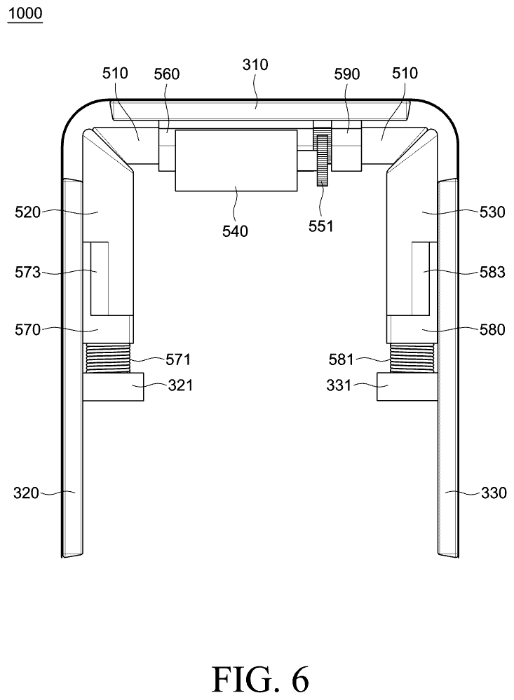

FIG. 1 is an exploded perspective view of a flexible display device according to one embodiment of the present disclosure. FIG. 2 is a perspective view of the flexible display device according to one embodiment of the present disclosure. FIG. 3 is a rear view of the flexible display device according to one embodiment of the present disclosure. FIG. 4 is a plan view of the flexible display device according to one embodiment of the present disclosure. FIG. 5 is a perspective view illustrating an appearance of the flexible display device according to one embodiment of the present disclosure after a bending operation. FIG. 6 is a plan view illustrating the appearance of the flexible display device according to one embodiment of the present disclosure after the bending operation.

Referring to FIGS. 1 to 6, a flexible display device 1000 according to one embodiment of the present disclosure includes a cover window 100, a display panel 200, a plurality of back plates 300, a printed circuit board 400, and a driving module 500.

The cover window 100 is disposed on the front surface of the display panel 200. The cover window 100 protects the display panel 200. The cover window 100 is disposed on the display panel 200 to protect the display panel 200 from external impact or scratches. The cover window 100 is made of a light-transmitting material so that an image implemented in the display panel 200 is displayed to the outside. The cover window 100 may be formed of tempered glass, plastic, or a transparent polymer material.

The cover window 100 has a flexibility so that the cover window 100 can be bent together with the display panel 200 according to the bending operation of the display panel 200. The cover window 100 has a strength that can stably protect the display panel 200 even in a bent state. The cover window 100 may cover the entire front area of the display panel 200. The cover window 100 may have substantially the same size as the display panel 200. The thickness of the cover window 100 may be set so that interference does not occur during bending of the display panel 200.

The display panel 200 is disposed on the back surface of the cover window 100. The display panel 200 is a panel that displays an image. The display panel 200 may be any one of a plasma display panel, a liquid crystal display (or liquid crystal display panel), an organic light emitting diode display (or organic light emitting diode display panel), and a light emitting diode display (or light emitting diode display panel).

The display panel 200 includes a plurality of pixels. The plurality of pixels may include a light-emitting element and a driving circuit. The driving circuit controls the light-emitting element according to a signal transmitted from a printed circuit board 400. The display panel 200 is electrically connected to the driving circuit to display an image according to the image signal.

The display panel 200 is formed on a flexible substrate and may be bent. The display panel 200 may be bent, for example, in a ‘ [symbol] ’ shape, according to a bending operation of the plurality of back plates 300.

Although not illustrated in the drawings, an adhesive layer may be disposed between the cover window 100 and the display panel 200. The adhesive layer adheres the cover window 100 and the display panel 200. The adhesive layer may be formed of a transparent adhesive layer so that an image of the display panel 200 may be recognized. For example, the adhesive layer may be formed of an optical clear adhesive (OCA), but is not limited thereto.

The plurality of back plates 300 are disposed on the back surface of the display panel 200. The plurality of back plates 300 are made of a metal material or a rigid non-metal material and may support and protect the display panel 200.

The plurality of back plates 300 include a mid-back plate 310, a first side back plate 320, and a second side back plate 330.

The mid-back plate 310 is disposed on the back surface of a central area of the display panel 200. The mid-back plate 310 may serve as a reference during the bending operation of the first side back plate 320 and the second side back plate 330. When the first side back plate 320 and the second side back plate 330 are bent, the outer end portions thereof may be moved toward the back surface of the mid-back plate 310.

The mid-back plate 310 may be made of a lightweight, high-strength metal material such as aluminum or a high-strength non-metal material such as reinforced plastic or carbon fiber reinforced plastic to support the display panel 200. The mid-back plate 310 may reinforce the central portion of the display panel 200 to suppress warping or twisting of the display panel 200.

The first side back plate 320 may be disposed on the back surface of one side area of the display panel 200, and the second side back plate 330 may be disposed on the back surface of the other side area of the display panel 200.

The first side back plate 320 and the second side back plate 330 are each installed rotatably with respect to the mid-back plate 310. The first side back plate 320 and the second side back plate 330 may be formed of a material identical to or similar to a material of the mid-back plate 310. The first side back plate 320 and the second side back plate 330 may have a strength capable of withstanding stress that may occur during a bending operation.

The plurality of back plates 300 may further include a heat dissipation hole 301 disposed at a position corresponding to an area where the printed circuit board 400 is disposed. The heat dissipation hole 301 discharges heat generated from the printed circuit board 400 to the outside. In one embodiment, when the printed circuit board 400 is disposed between the display panel 200 and the first side back plate 320, the heat dissipation hole 301 that discharges heat generated from the printed circuit board 400 to the outside is disposed in the first side back plate 320.

Although not illustrated in the drawings, an adhesive layer may be disposed between the display panel 200 and the plurality of back plates 300. The adhesive layer adheres the display panel 200 and the plurality of back plates 300. The adhesive layer may be a double-sided tape or a transparent adhesive such as an optical clear adhesive (OCA). The adhesive layer provides adhesive force between the display panel 200 and the plurality of back plates 300. The adhesive layer suppresses a separation of the display panel 200 from the plurality of back plates 300. The adhesive layer may be disposed only in an area where the printed circuit board 400 is not disposed, so as to facilitate heat dissipation of the printed circuit board 400, but is not limited thereto.

The printed circuit board 400 is disposed on the back surface of the display panel 200. The printed circuit board 400 may be disposed between the display panel 200 and the plurality of back plates 300.

The printed circuit board 400 is a board on which various circuit elements for driving the display panel 200 are mounted. The printed circuit board 400 supplies various control signals and power for driving a display (or display panel), and performs functions such as image signal processing, power management, and timing control.

The printed circuit board 400 may be disposed in a portion of the display panel 200. The printed circuit board 400 may be disposed only in one side area, the other side area, or the central area of the display panel 200, thereby facilitating a bending operation of the display panel 200.

The driving module 500 is disposed on the back surface of the plurality of back plates 300. The driving module 500 may cause the first side back plate 320 and the second side back plate 330 to bend relative to the mid-back plate 310 so that the both end portions thereof are positioned (in other words, moved) toward the back surface of the mid-back plate 310 according to the driving of the driving module 500. The first side back plate 320 and the second side back plate 330 rotate counterclockwise and clockwise, respectively, relative to the mid-back plate 310 by the operation of the driving module 500, and as an example, causes the display panel 200 to bend in a ‘ [symbol] ’shape.

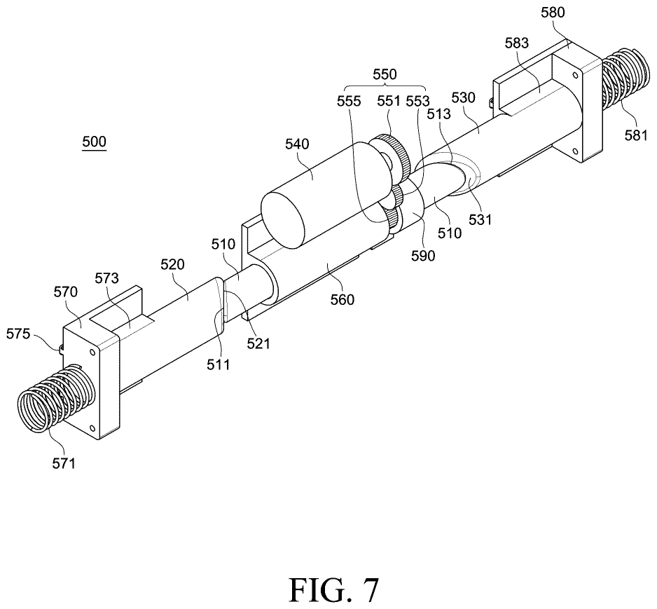

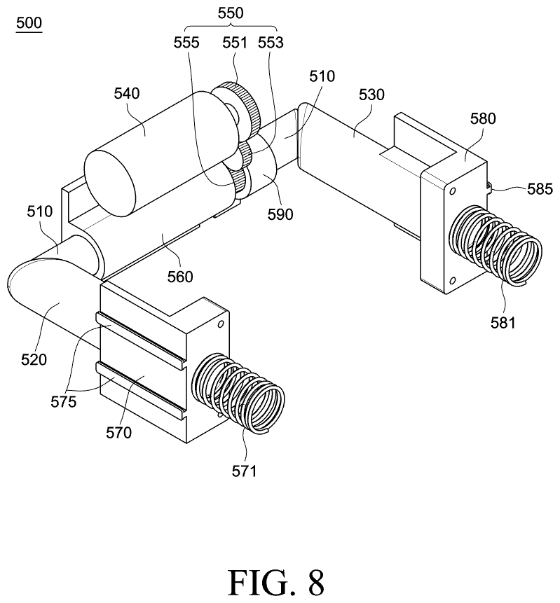

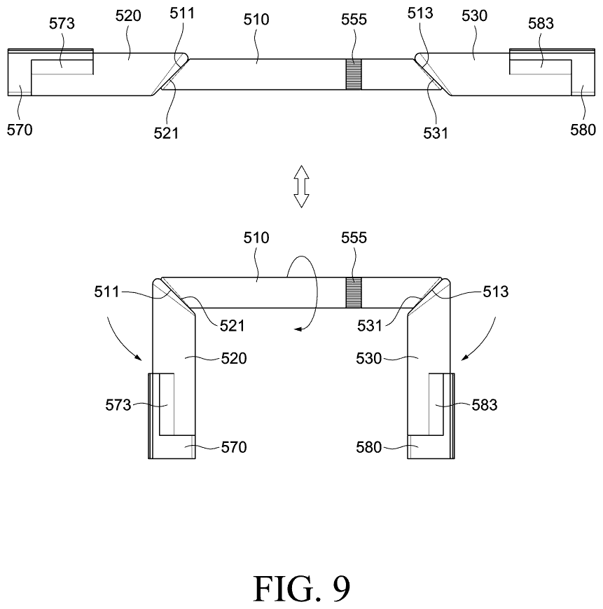

FIG. 7 is a perspective view of the driving module of the flexible display device according to one embodiment of the present disclosure. FIG. 8 is a perspective view illustrating the appearance of the driving module of the flexible display device according to one embodiment of the present disclosure after a bending operation. FIG. 9 is a plan view illustrating a driving process of first to third shafts of the flexible display device according to one embodiment of the present disclosure.

Referring to FIGS. 7 to 9 together, the driving module 500 includes a first shaft 510, a second shaft 520, a third shaft 530, a driving motor 540, and a power transmission gear assembly 550. In addition, the driving module 500 further includes a first coupling member 560 that supports the first shaft 510 on the back surface of the mid-back plate 310, a second coupling member 570 that supports the second shaft 520 on the back surface of the first side back plate 320, and a third coupling member 580 that supports the third shaft 530 on the back surface of the second side back plate 330. The driving module 500 may further include a fourth coupling member 590 that supports the first shaft 510 on the back surface of the mid-back plate 310.

The first shaft 510 is rotatably disposed on the back surface of the mid-back plate 310. The first shaft 510 is rotatably disposed in the hollow portions of the first coupling member 560 and the fourth coupling member 590. The first shaft 510 may rotate in the hollow portions of the first coupling member 560 and the fourth coupling member 590 by driving of the driving motor 540.

The first shaft 510 rotates in one direction or the other direction around a central axis thereof by driving of the driving motor 540.

The first shaft 510 includes a first inclined surface 511 and a second inclined surface 513 at both end portions respectively. The first inclined surface 511 is disposed at one end portion of the first shaft 510, and the second inclined surface 513 is disposed at the other end portion of the first shaft 510.

The second shaft 520 is pivotally disposed on the back surface of the first side back plate 320. The second shaft 520 may receive a rotational force from the first shaft 510 and pivotally move. A third inclined surface 521 is disposed at one end portion of the second shaft 520. The third inclined surface 521 is in contact with the first inclined surface 511. The third inclined surface 521 is disposed in a form that is in contact with the first inclined surface 511 of the first shaft 510 and may be pressed by the first inclined surface 511 during a rotating process of the first shaft 510 (in other words, as the first shaft 510 rotates).

The third shaft 530 is pivotally disposed on the back surface of the second side back plate 330. The third shaft 530 receives rotational force from the first shaft 510 and pivotally moves. A fourth inclined surface 531 is disposed at one end portion of the third shaft 530. The fourth inclined surface 531 is in contact with the second inclined surface 513. The fourth inclined surface 531 is disposed in a form that is in contact with the second inclined surface 513 of the first shaft 510 and may be pressed by the second inclined surface 513 during a rotating process of the first shaft 510 (in other words, as the first shaft 510 rotates).

The second shaft 520 and the third shaft 530 are disposed in a straight line with the first shaft 510 or inclined with respect to the first shaft 510 by the rotation of the first shaft 510, respectively. The rotational force of the first shaft 510 can be transmitted to the second shaft 520 and the third shaft 530 through the first to fourth inclined surfaces 511, 513, 521, and 531. The rotational force of the first shaft 510 can be transmitted to the second shaft 520 and the third shaft 530 through the first inclined surface 511 and the second inclined surface 513 disposed at both end portions of the first shaft 510 respectively, so that the first side back plate 320 and the second side back plate 330 can be moved and bent counterclockwise and clockwise respectively.

The driving motor 540 is disposed on the back surface of the mid-back plate 310. The driving motor 540 may be an electric motor, which is a driving source that converts electrical energy into mechanical rotational motion. Alternatively, the driving motor 540 may be a hydraulic motor or a pneumatic motor, but is not limited thereto. The driving motor 540 may be a bidirectional motor capable of forward and reverse rotation. The driving motor 540 may provide a stationary torque for maintaining a bent state of the display panel. The driving motor 540 may be a stepping motor or a servo motor capable of precisely controlling the rotational speed of the rotation shaft, but is not limited thereto.

The power transmission gear assembly 550 may transmit the rotational force of the driving motor 540 to the first shaft 510.

The power transmission gear assembly 550 may include a first gear 551 installed on the rotation shaft of the driving motor 540, a second gear 553 meshing with the first gear 551, and a third gear 555 meshing with the second gear 553 and installed on the first shaft 510.

The first gear 551 is coupled to the rotation shaft of the driving motor 540 and rotated by the driving of the driving motor 540. The first gear 551 rotates in the same direction as the rotation shaft of the driving motor 540 and transmits the rotational force of the driving motor 540 to the second gear 553.

The second gear 553 rotates in mesh with the first gear 551. The second gear 553 rotates in the opposite direction to the rotation shaft of the driving motor 540 and transmits the rotational force of the driving motor 540 to the third gear 555. The second gear 553 may be an idle gear disposed between the first gear 551 and the third gear 555. Although not illustrated, the rotation shaft of the second gear 553 may be coupled to the first coupling member 560 and the fourth coupling member 590 to rotate on the back surface of the mid-back plate 310. However, the present disclosure is not limited thereto, and the rotation shaft of the second gear 553 may also be coupled to the mid-back plate 310. The second gear 553 may be disposed when the distance between the first gear 551 and the third gear 555 is far, but is not limited thereto.

The third gear 555 is disposed on the first shaft 510. The third gear 555 may be installed on the first shaft 510 so as to rotate together with the first shaft 510. The third gear 555 rotates in mesh with the second gear 553. The third gear 555 may rotate in the same direction as the rotation shaft of the driving motor 540.

The first coupling member 560 is coupled to the back surface of the mid-back plate 310. The first coupling member 560 rotatably supports the first shaft 510 on the back surface of the mid-back plate 310. The first coupling member 560 has a hollow portion into which the first shaft 510 is inserted. The first shaft 510 may rotate within the hollow portion of the first coupling member 560. The inner diameter of the hollow portion of the first coupling member 560 has a size corresponding to the outer diameter of the first shaft 510.

The second coupling member 570 is disposed at the other end portion of the second shaft 520. The second coupling member 570 is coupled to the back surface of the first side back plate 320. When the second shaft 520 receives a rotational force from the first shaft 510 and pivots, the first side back plate 320 coupled with the second coupling member 570 pivots counterclockwise with respect to the mid-back plate 310 and moves toward the back surface of the mid-back plate 310.

A first elastic body 571 is disposed on one end portion of the second coupling member 570, and a first support member 321 that supports the first elastic body 571 is disposed on the back surface of the first side back plate 320. The first elastic body 571 is disposed between one end portion of the second coupling member 570 and the first support member 321.

When the second shaft 520 receives a rotational force from the first shaft 510 and pivotally moves the first side back plate 320 counterclockwise, a load applied in a horizontal direction may be generated on the second shaft 520.

The first elastic body 571 absorbs the load generated when the second shaft 520 rotates, so that the first side back plate 320 can be smoothly bent. In addition, the first elastic body 571 may absorb the repulsive force generated when the second shaft 520 pivotally moves the first side back plate 320 counterclockwise.

In one embodiment, the first elastic body 571 may be a spring, and in this case, the first elastic body 571 may also be referred to as a first spring. The first elastic body 571 may enable the bending operation of the first side back plate 320 to be performed smoothly. The first elastic body 571 may alleviate shock or vibration occurring during the bending operation, and may stably maintain the position of the first side back plate 320 in a bent state.

The second coupling member 570 includes a first extension 573 at a location where the second shaft 520 is disposed. The first extension 573 increases the coupling force between the second shaft 520 and the second coupling member 570. The first extension 573 extends along a portion of an outer circumference of the second shaft 520 to a certain length. Since the portion of the first extension 573 that is in contact with the second shaft 520 extends, the coupling force between the second shaft 520 and the second coupling member 570 can be increased. The first extension 573 allows the second coupling member 570 to move stably together with the second shaft 520 when the second shaft 520 pivots. The first extension 573 increases the coupling force between the second shaft 520 and the second coupling member 570, thereby ensuring stability of the bending operation and ensuring that the coupled state is maintained even during repeated bending operations.

The second coupling member 570 includes at least one first insertion member 575. The first insertion member 575 may be inserted into an insertion groove formed on the back surface of the first side back plate 320 and then fit-coupled with the first side back plate 320. The first insertion member 575 fixes the second coupling member 570 to the first side back plate 320. The fit-coupling structure of the first insertion member 575 suppresses the separation of the second coupling member 570 from the first side back plate 320 during the bending operation of the flexible display device 1000.

The third coupling member 580 is disposed at the other end portion of the third shaft 530. The third coupling member 580 is coupled to the back surface of the second side back plate 330. When the third shaft 530 receives the rotational force from the first shaft 510 and is pivoted, the second side back plate 330 coupled with the third coupling member 580 pivots clockwise with respect to the mid-back plate 310 and moves toward the back surface of the mid-back plate 310.

A second elastic body 581 is disposed on one end portion of the third coupling member 580, and a second support member 331 that supports the second elastic body 581 is disposed on the back surface of the second side back plate 330. The second elastic body 581 is disposed between one end portion of the third coupling member 580 and the second support member 331.

When the third shaft 530 receives the rotational force from the first shaft 510 and pivotally moves the second side back plate 330 clockwise, a load that is applied in the horizontal direction may be generated in the third shaft 530.

The second elastic body 581 absorbs the load generated when the third shaft 530 rotates, so that the second side back plate 330 can be bent smoothly with respect to the mid-back plate 310. In addition, the second elastic body 581 can absorb the repulsive force generated when the third shaft 530 pivotally moves the second side back plate 330 clockwise.

For example, the second elastic body 581 may be a spring, and in this case, the second elastic body 581 may also be referred to as a second spring. The second elastic body 581 may Page 18 enable the bending operation of the second side back plate 330 to be performed smoothly. The second elastic body 581 may alleviate shock or vibration occurring during the bending operation, and may stably maintain the position of the second side back plate 330 in a bent state.

The third coupling member 580 includes a second extension 583 at a location where the third shaft 530 is disposed. The second extension 583 increases the coupling force between the third shaft 530 and the third coupling member 580. The second extension 583 extends along a portion of an outer circumference of the third shaft 530 to a certain length. Since the portion of the second extension 583 that is in contact with the third shaft 530 extends, the coupling force between the third shaft 530 and the third coupling member 580 can be increased. The second extension 583 allows the third coupling member 580 to move stably together with the third shaft 530 when the third shaft 530 pivots. The second extension 583 increases the coupling force between the third shaft 530 and the third coupling member 580, thereby ensuring stability of the bending operation and ensuring that the coupled state is maintained even during repeated bending operations.

The third coupling member 580 includes at least one second insertion member 585. The second insertion member 585 may be inserted into an insertion groove formed on the back surface of the second side back plate 330 and then fit-coupled with the second side back plate 330. The second insertion member 585 fixes the third coupling member 580 to the second side back plate 330. The fit-coupling structure of the second insertion member 585 suppresses the separation of the third coupling member 580 from the second side back plate 330 during the bending operation of the flexible display device 1000.

The fourth coupling member 590 is connected to the back surface of the mid-back plate 310. The fourth coupling member 590 is spaced apart from the first coupling member 560. The third gear 555 may be disposed between the first coupling member 560 and the fourth coupling member 590.

The fourth coupling member 590 rotatably supports the first shaft 510 on the back surface of the mid-back plate 310. The fourth coupling member 590 has a hollow portion into which the first shaft 510 is inserted. The first shaft 510 may rotate within the hollow portion of the fourth coupling member 590. The inner diameter of the hollow portion of the fourth coupling member 590 has a size corresponding to the outer diameter of the first shaft 510.

The driving module 500 performs the bending operation by pivoting the first side back plate 320 and the second side back plate 330 toward the back surface of the mid-back plate 310 through the rotational operation of the first shaft 510 and the pivotal operations of the second shaft 520 and the third shaft 530.

The operation process of the driving module 500 is summarized as follows, for example, with reference to FIG. 9.

When the first shaft 510 is rotated by the driving motor 540, the first inclined surface 511 of the first shaft 510 presses the third inclined surface 521 of the second shaft 520, and the second inclined surface 513 of the first shaft 510 presses the fourth inclined surface 531 of the third shaft 530.

Since the first inclined surface 511 of the first shaft 510 and the third inclined surface 521 of the second shaft 520 are in contact with each other, the second shaft 520 can pivotally move in the process of the third inclined surface 521 being pressed by the first inclined surface 511. Similarly, since the second inclined surface 513 of the first shaft 510 and the fourth inclined surface 531 of the third shaft 530 are in contact with each other, the third shaft 530 can pivotally move in the process of the fourth inclined surface 531 being pressed by the second inclined surface 513.

In the process of the second shaft 520 being pivotally moved by the rotational force transmitted from the first shaft 510, the first side back plate 320 coupled with the second coupling member 570 supporting the second shaft 520 can pivotally move counterclockwise with respect to the mid-back plate 310.

In addition, during the process in which the third shaft 530 is pivotally moved by the rotational force transmitted from the first shaft 510, the second side back plate 330 coupled with the third coupling member 580 that supports the third shaft 530 can pivotally move clockwise with respect to the mid-back plate 310.

The driving module 500 converts the rotational force of the first shaft 510 by the driving motor 540 into pivotal movement of the second shaft 520 and the third shaft 530 via the first to fourth inclined surfaces 511, 513, 521, and 531, thereby bending the first side back plate 320 and the second side back plate 330 in a counterclockwise and clockwise direction respectively with respect to the mid-back plate 310.

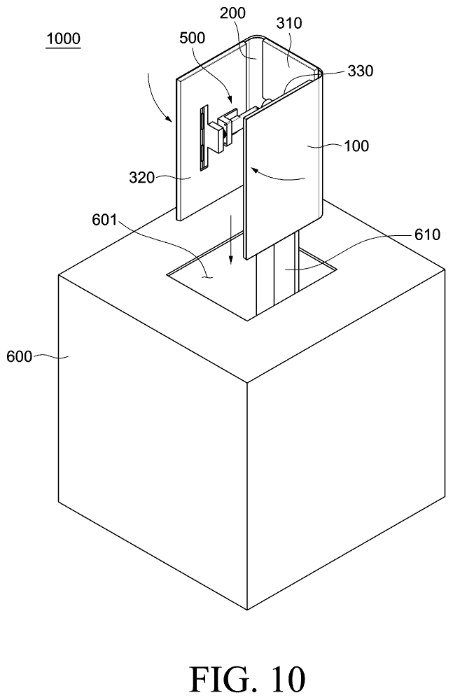

FIG. 10 is a perspective view illustrating a flexible display device according to one embodiment of the present disclosure being accommodated in a housing.

A flexible display device 1000 according to one embodiment of the present disclosure is equipped with a housing 600 and a lifting/lowering module 610.

The housing 600 provides an accommodation space 601 for storing the flexible display device 1000. The housing 600 includes an opening on the upper surface thereof through which the flexible display device 1000 can be raised and lowered. The opening has a size that allows the flexible display device 1000 to move in a bent state. The internal space of the housing 600 may have a size that allows the flexible display device 1000 in a bent state to be completely accommodated.

The lifting/lowering module 610 can raise the flexible display device 1000 in a bent state from the housing 600 and lower the flexible display device 1000 in a bent state into the housing 600. The lifting/lowering module 610 is coupled to the back surface of the mid-back plate 310 and can move the entire flexible display device 1000. The lifting/lowering module 610 has a structure capable of stably supporting the weight of the flexible display device 1000.

The operation process of the lifting/lowering module 610 is described as follows.

The flexible display device 1000 is configured such that each of the first side back plate 320 and the second side back plate 330 can be each bent with respect to the mid-back plate 310 by the driving module 500. The lifting/lowering module 610 can lower the flexible display device 1000 in a bent state into the housing 600 and stores the flexible display device 1000 in the accommodation space 601. In this case, the bent state of the flexible display device 1000 is maintained. In order to use the flexible display device 1000, the lifting/lowering module 610 raises the flexible display device 1000 in the bent state from the housing 600 and moves the flexible display device 1000 to a preset display position.

The housing 600 may be installed inside a center fascia of a vehicle. The center fascia of the vehicle is a space where an air conditioning unit or an audio system is installed, and is located between the driver and the passenger seat. When the housing 600 is installed inside the center fascia, the flexible display device 1000 may be raised and lowered through an upper surface of the center fascia. In the flexible display device 1000 according to one embodiment of the present disclosure, when the vehicle ignition is turned on, the lifting/lowering module 610 operates to raise the flexible display device 1000 in a bent state toward the upper surface of the center fascia. After the flexible display device 1000 is rised toward the upper surface of the center fascia, the flexible display device 1000 may be unfolded into a flat shape by the driving operation of the driving module 500 (in this case, for example, the first shaft 510 will be rotated in a direction opposite to what shown in FIG. 9). When the vehicle ignition is turned off or the user wishes to accommodate the display (that is, the flexible display device), the lifting/lowering module 610 lowers the flexible display device 1000 in a bent state and safely stores the flexible display device 1000 in the housing 600 inside the center fascia.

Since the housing 600 is installed inside the center fascia, the flexible display device 1000 can efficiently utilize the space inside the vehicle when not in use, and can be protected from external impact or theft. In addition, the operation of the lifting/lowering module 610 and the bending state of the flexible display device 1000 may be controlled in conjunction with an electrical system of the vehicle.

The housing 600 may be installed in various locations within the vehicle. As described above, the housing 600 may be installed within the center fascia, but also may be installed within the front seat headrest for rear seat passengers, in the space between the driver and the passenger seat, or on the ceiling.

The flexible display device 1000 according to one embodiment of the present disclosure has a simple structure that can be bent in a ‘ [symbol] ’ shape, so that the size of the housing 600 can be minimized. This has a very important advantage in a limited space inside a vehicle. In particular, when installed in the area between the rear and front seats, the simplified bending structure and accommodation space 601 have even greater advantages. When the display panel 200 (in other words, the flexible display device 1000) is not in use, it is compactly accommodated by bending into a ‘ [symbol] ’ shape, so as not to obstruct the movement or view of the passenger, and when in use, the display panel 200 can be used by unfolding into a flat form.

The lifting/lowering module 610 is designed to operate stably in these various installation environments, so that the flexible display device 1000 can be smoothly raised and lowered and maintained in a bent state regardless of the installation location.

The flexible display device 1000 according to one embodiment of the present disclosure provides a structure capable of stable bending while suppressing an excessive stress or deformation applied to the display panel 200. The rotational force of the first shaft 510 can be transmitted to the second shaft 520 and the third shaft 530, so that the first side back plate 320 and the second side back plate 330 can pivot counterclockwise and clockwise respectively with respect to a mid-back plate 310, and so that the display panel 200 can be bent in a ‘ [symbol] ’shape.

In addition, the flexible display device 1000 according to one embodiment of the present disclosure can provide a structure that can absorb a load or a pushing force generated when each shaft rotates while being bendable with a simple mechanical structure, so that a lightweight flexible display device 1000 can be implemented.

In addition, the flexible display device 1000 according to one embodiment of the present disclosure provides a structure that is particularly suitable for a vehicle display. The accommodation space 601 can be minimized through a simple bending structure in the shape of a ‘ [symbol] ’, thereby enabling efficient use of a limited space within a vehicle.

In addition, the flexible display device 1000 according to one embodiment of the present disclosure can effectively release heat generated from the PCB through the heat dissipation hole 301, thereby improving the reliability of the display device, and can safely accommodate the display device in a bent state through a lifting/lowering module 610 within a housing 600, thereby greatly improving user convenience.

As a result, the flexible display device 1000 according to one embodiment of the present disclosure can provide an innovative solution that satisfies both the functionality and practicality of a vehicle display through a simple yet stable bending structure.

The exemplary embodiments of the present disclosure can also be described as follows:

According to an aspect of the present disclosure, there is provided a flexible display device. The flexible display device comprises a plurality of back plates disposed on a back surface of the display panel, and a driving module for rotating at least one of the plurality of back plates with respect to another one of the plurality of back plates so that the display panel can be bent, wherein the driving module includes a rotatable shaft rotatably disposed on a back surface of the another one of the plurality of back plates, a pivotable shaft pivotally disposed on a back surface of the at least one of the plurality of back plates and pivoted by receiving a rotational force from the rotatable shaft, and a rotary power driving source disposed on the back surface of the another one of the plurality of back plates and for rotating the rotatable shaft.

The plurality of back plates may comprises a mid-back plate, a first side back plate, and a second side back plate disposed on the back surface of the display panel. The driving module may be configured to rotate the first side back plate and the second side back plate with respect to the mid-back plate. The driving module may include a first shaft rotatably disposed on a back surface of the mid-back plate, a second shaft pivotally disposed on a back surface of the first side back plate and pivoted by receiving a rotational force from the first shaft, a third shaft pivotally disposed on a back surface of the second side back plate and pivoted by receiving a rotational force from the first shaft, and a motor disposed on the back surface of the mid-back plate and for rotating the first shaft.

The display panel may be bent in a ‘ [symbol] ’shape.

The first shaft may include a first inclined surface and a second inclined surface respectively at both end portions thereof. The second shaft may include a third inclined surface that is in contact with the first inclined surface at one end portion thereof. The third shaft may include a fourth inclined surface that is in contact with the second inclined surface at one end portion thereof. When the first shaft rotates, the first inclined surface and the third inclined surface may mesh with each other and the second inclined surface and the fourth inclined surface may mesh with each other so that the second shaft and the third shaft may pivot.

The flexible display device may further comprise a first coupling member which is coupled to the back surface of the mid-back plate and into which the first shaft is inserted, a second coupling member coupled to the back surface of the first side back plate and disposed at the other end portion of the second shaft, and a third coupling member coupled to the back surface of the second side back plate and disposed at the other end portion of the third shaft.

The second coupling member may include a first extension at a location where the second shaft is disposed, and the first extension may extend along a portion of an outer circumference of the second shaft to a certain length. The third coupling member may include a second extension at a location where the third shaft is disposed, and the second extension may extend along a portion of an outer circumference of the third shaft to a certain length.

The second coupling member may include at least one first insertion member, the at least one first insertion member may be inserted into an insertion groove formed on the back surface of the first side back plate and fit-coupled with the first side back plate. The third coupling member may include at least one second insertion member, the at least one second insertion member may be inserted into an insertion groove formed on the back surface of the second side back plate and then fit-coupled with the second side back plate.

The flexible display device may further comprise a first support member disposed on the back surface of the first side back plate, a second support member disposed on the back surface of the second side back plate, a first elastic body disposed at one end portion of the second coupling member and absorbing a repulsive force generated when the second shaft pivots, between the first support member and the one end portion of the second coupling member; and a second elastic body disposed at one end portion of the third coupling member and absorbing a repulsive force generated when the third shaft pivots, between the second support member and the one end portion of the third coupling member.

The driving module may further include a power transmission gear assembly that is rotated by the motor and rotates the first shaft, and the power transmission gear assembly transmits a rotational force of the motor to the first shaft.

The flexible display device may further comprise a fourth coupling member coupled to the back surface of the mid-back plate, into which the first shaft is inserted, and spaced apart from the first coupling member, wherein the power transmission gear assembly may be connected between the first coupling member and the fourth coupling member.

The first side back plate and the second side back plate may be bent toward the back surface of the mid-back plate by the second shaft and the third shaft respectively, and during the bending of first side back plate and the second side back plate, the second shaft and the third shaft are pivoted by rotation of the first shaft respectively.

The flexible display device may be equipped with a housing, and a lifting/lowering module coupled to the back surface of the mid-back plate and for raising the flexible display device in a bent state from the housing or lowering the flexible display device in a bent state into the housing.

The flexible display device may further comprise a printed circuit board disposed on the back surface of the display panel, wherein the mid-back plate, the first side back plate, or the second side back plate may include a heat dissipation hole disposed in an area where the printed circuit board is disposed.

An adhesive layer may be disposed between the display panel and the plurality of back plates, and the adhesive layer may be disposed only in an area where the printed circuit board is not disposed.

According to an aspect of the present disclosure, there is provided a flexible display device. The flexible display device comprises a cover window, a display panel disposed on a back surface of the cover window, a plurality of back plates disposed on a back surface of the display panel, a coupling member disposed on a back surface of at least one of the plurality of back plates and coupled with a pivotable shaft, another coupling member disposed on a back surface of another one of the plurality of back plates and into which a rotatable shaft is inserted, and a rotary power driving source for rotating the rotatable shaft, wherein the pivotable shaft is pivoted by receiving a rotational force from the rotatable shaft, and the at least one of the plurality of back plates is rotated with respect to the another one of the plurality of back plates by the pivoting of the pivotable shaft, so that the display panel and the cover window can be bent together.

The plurality of back plates may comprise a mid-back plate, a first side back plate, and a second side back plate disposed on the back surface of the display panel. The coupling member and the another coupling member may include a first coupling member disposed on a back surface of the mid-back plate and into which a first shaft is inserted, a second coupling member disposed on a back surface of the first side back plate and coupled with a second shaft, a third coupling member disposed on a back surface of the second side back plate and coupled with a third shaft. The rotary power driving source may ne configured to be a motor for rotating the first shaft. The second shaft and the third shaft may be pivoted respectively by receiving a rotational force from the first shaft. The first side back plate and the second side back plate may be rotated counterclockwise and clockwise respectively with respect to the mid-back plate by the pivoting of the second shaft and the third shaft, so that the display panel and the cover window can be bent together.

The first shaft may include a first inclined surface disposed at one end thereof and a second inclined surface disposed at the other end thereof. The second shaft may include a third inclined surface that is in contact with the first inclined surface and receives a rotational force from the first shaft. The third shaft may include a fourth inclined surface that is in contact with the second inclined surface and receives rotational force from the first shaft.

The flexible display device may further comprise a fourth coupling member which is spaced apart from the first coupling member and disposed on the back surface of the mid-back plate, and into which the first shaft is inserted; and a power transmission gear assembly disposed between the first coupling member and the fourth coupling member and transmitting driving force of the motor to the first shaft.

The power transmission gear assembly may include a first gear installed on a rotation shaft of the motor, a second gear meshing with the first gear, and a third gear installed on the first shaft and meshing with the second gear.

The flexible display device may further comprise a first support member disposed on the back surface of the first side back plate, a second support member disposed on the back surface of the second side back plate, a first spring disposed between the first support member and the second coupling member and absorbing a load generated when the second shaft pivots. and a second spring disposed between the second support member and the third coupling member and absorbing a load generated when the third shaft pivots.

The flexible display device may be equipped with a housing in which the flexible display device is accommodated, and a lifting/lowering module coupled to the back surface of the mid-back plate and for raising or lowering the flexible display device, wherein the lifting/lowering module may be lowered to move the flexible display device into the housing in a state where the first side back plate and the second side back plate are rotated and bent toward the back surface of the mid-back plate.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

1. A flexible display device, comprising:
a display panel;
a plurality of back plates disposed on a back surface of the display panel; and
a driving module for rotating at least one of the plurality of back plates with respect to another one of the plurality of back plates so that the display panel can be bent,
wherein the driving module includes:
a rotatable shaft rotatably disposed on a back surface of the another one of the plurality of back plates,
a pivotable shaft pivotally disposed on a back surface of the at least one of the plurality of back plates and pivoted by receiving a rotational force from the rotatable shaft, and
a rotary power driving source disposed on the back surface of the another one of the plurality of back plates and for rotating the rotatable shaft, and
wherein a rotational axis of the rotatable shaft and a rotational axis of the pivotable shaft extend in a direction perpendicular to the bending direction of the display panel.

2. The flexible display device according to claim 1, wherein the plurality of back plates comprises a mid-back plate, a first side back plate, and a second side back plate disposed on the back surface of the display panel,
the driving module is configured to rotate the first side back plate and the second side back plate with respect to the mid-back plate, and
the driving module includes
a first shaft rotatably disposed on a back surface of the mid-back plate,
a second shaft pivotally disposed on a back surface of the first side back plate and pivoted by receiving a rotational force from the first shaft,
a third shaft pivotally disposed on a back surface of the second side back plate and pivoted by receiving a rotational force from the first shaft, and
a motor disposed on the back surface of the mid-back plate and for rotating the first shaft.

3. The flexible display device according to claim 2, wherein the display panel is bent in a ‘ [symbol] ’ shape.

4. The flexible display device according to claim 2, wherein the first shaft includes a first inclined surface and a second inclined surface respectively at both end portions thereof,
the second shaft includes a third inclined surface that is in contact with the first inclined surface at one end portion thereof,
the third shaft includes a fourth inclined surface that is in contact with the second inclined surface at one end portion thereof, and
when the first shaft rotates, the first inclined surface and the third inclined surface mesh with each other and the second inclined surface and the fourth inclined surface mesh with each other so that the second shaft and the third shaft pivot.

5. The flexible display device according to claim 4, further comprising:
a first coupling member which is coupled to the back surface of the mid-back plate and into which the first shaft is inserted;
a second coupling member coupled to the back surface of the first side back plate and disposed at the other end portion of the second shaft; and
a third coupling member coupled to the back surface of the second side back plate and disposed at the other end portion of the third shaft.

6. The flexible display device according to claim 5, wherein
the second coupling member includes a first extension at a location where the second shaft is disposed, and the first extension extends along a portion of an outer circumference of the second shaft to a certain length; and/or the third coupling member includes a second extension at a location where the third shaft is disposed, and the second extension extends along a portion of an outer circumference of the third shaft to a certain length.

7. The flexible display device according to claim 5, wherein the second coupling member includes at least one first insertion member, the at least one first insertion member is inserted into an insertion groove formed on the back surface of the first side back plate and fit-coupled with the first side back plate; and/or the third coupling member includes at least one second insertion member, the at least one second insertion member is inserted into an insertion groove formed on the back surface of the second side back plate and then fit-coupled with the second side back plate.

8. The flexible display device according to claim 5, further comprising:
a first support member disposed on the back surface of the first side back plate;
a second support member disposed on the back surface of the second side back plate;
a first elastic body disposed at one end portion of the second coupling member and absorbing a repulsive force generated when the second shaft pivots, between the first support member and the one end portion of the second coupling member; and
a second elastic body disposed at one end portion of the third coupling member and absorbing a repulsive force generated when the third shaft pivots, between the second support member and the one end portion of the third coupling member.

9. The flexible display device according to claim 5, wherein the driving module further includes a power transmission gear assembly that is rotated by the motor and rotates the first shaft, and
the power transmission gear assembly transmits a rotational force of the motor to the first shaft.

10. The flexible display device according to claim 9, further comprising a fourth coupling member coupled to the back surface of the mid-back plate, into which the first shaft is inserted, and spaced apart from the first coupling member,
wherein the power transmission gear assembly is connected between the first coupling member and the fourth coupling member.

11. The flexible display device according to claim 2, wherein the first side back plate and the second side back plate can be bent toward the back surface of the mid-back plate by the second shaft and the third shaft respectively, and during the bending of the first side back plate and the second side back plate, the second shaft and the third shaft are pivoted by rotation of the first shaft respectively.

12. The flexible display device according to claim 2, wherein the flexible display device is equipped with:
a housing; and
a lifting/lowering module coupled to the back surface of the mid-back plate and for raising the flexible display device in a bent state from the housing or lowering the flexible display device in a bent state into the housing.

13. The flexible display device according to claim 2, further comprising a printed circuit board disposed on the back surface of the display panel,
wherein the mid-back plate, the first side back plate, or the second side back plate includes a heat dissipation hole disposed in an area where the printed circuit board is disposed.

14. The flexible display device according to claim 13, wherein an adhesive layer is disposed between the display panel and the plurality of back plates, and the adhesive layer is disposed only in an area where the printed circuit board is not disposed.

15. A flexible display device, comprising:
a cover window;
a display panel disposed on a back surface of the cover window;
a plurality of back plates disposed on a back surface of the display panel;
a coupling member disposed on a back surface of at least one of the plurality of back plates and coupled with a pivotable shaft;
another coupling member disposed on a back surface of another one of the plurality of back plates and into which a rotatable shaft is inserted; and
a rotary power driving source for rotating the rotatable shaft,
wherein the pivotable shaft is pivoted by receiving a rotational force from the rotatable shaft, and
the at least one of the plurality of back plates is rotated with respect to the another one of the plurality of back plates by the pivoting of the pivotable shaft, so that the display panel and the cover window can be bent together, and
wherein a rotational axis of the rotatable shaft and a rotational axis of the pivotable shaft extend in a direction perpendicular to the bending direction of the display panel and cover window.

16. The flexible display device according to claim 15, wherein the plurality of back plates comprises a mid-back plate, a first side back plate, and a second side back plate disposed on the back surface of the display panel,
the coupling member and the another coupling member include
a first coupling member disposed on a back surface of the mid-back plate and into which a first shaft is inserted;
a second coupling member disposed on a back surface of the first side back plate and coupled with a second shaft; and
a third coupling member disposed on a back surface of the second side back plate and coupled with a third shaft,
wherein the rotary power driving source is configured to be a motor for rotating the first shaft,
the second shaft and the third shaft are pivoted respectively by receiving a rotational force from the first shaft, and
the first side back plate and the second side back plate are rotated counterclockwise and clockwise respectively with respect to the mid-back plate by the pivoting of the second shaft and the third shaft, so that the display panel and the cover window can be bent together.

17. The flexible display device according to claim 16, wherein the first shaft includes a first inclined surface disposed at one end thereof and a second inclined surface disposed at the other end thereof,
the second shaft includes a third inclined surface that is in contact with the first inclined surface and receives a rotational force from the first shaft, and
the third shaft includes a fourth inclined surface that is in contact with the second inclined surface and receives a rotational force from the first shaft.

18. The flexible display device according to claim 16, further comprising:
a fourth coupling member which is spaced apart from the first coupling member and disposed on the back surface of the mid-back plate, and into which the first shaft is inserted; and
a power transmission gear assembly disposed between the first coupling member and the fourth coupling member and transmitting a driving force of the motor to the first shaft.

19. The flexible display device according to claim 18, wherein the power transmission gear assembly includes
a first gear installed on a rotation shaft of the motor,
a second gear meshing with the first gear, and
a third gear installed on the first shaft and meshing with the second gear.

20. The flexible display device according to claim 16, further comprising:
a first support member disposed on the back surface of the first side back plate;
a second support member disposed on the back surface of the second side back plate;
a first spring disposed between the first support member and the second coupling member and absorbing a load generated when the second shaft pivots; and
a second spring disposed between the second support member and the third coupling member and absorbing a load generated when the third shaft pivots.

21. The flexible display device according to claim 16, wherein the flexible display device is equipped with:
a housing in which the flexible display device is accommodated; and
a lifting/lowering module coupled to the back surface of the mid-back plate and for raising or lowering the flexible display device,
wherein the lifting/lowering module is lowered to move the flexible display device into the housing in a state where the first side back plate and the second side back plate are rotated and bent toward the back surface of the mid-back plate.
